(19) United States
(12) Patent Application Publication
(10) Pub. No.: US 2006/0103437 A1
(43) Pub. Date: May 18, 2006

(54) Power-on reset circuit

(75) Inventor: Khil Ohk Kang, Gyeonggi-do (KR)

Correspondence Address: HELLER EHRMAN WHITE & MCAULIFFE LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 11/115,365

(22) Filed: Apr. 27, 2005

(30) Foreign Application Priority Data
Nov. 15, 2004 (KR) 10-2004-0093225

(51) Int. Cl. H03L 7/00

(52) U.S. Cl. 327/143

(57) ABSTRACT

A power-on reset circuit senses levels of internal power voltage including a boosting voltage and a core voltage as well as an external power voltage, and outputs a power-on reset signal when the voltages are all over a predetermined level, thereby improving stability of an initializing operation. The power-on reset circuit comprises an external power voltage detecting unit, a plurality of internal power voltage detecting units and a selective output unit.

### BACKGROUND OF THE INVENTION

1. Field of the Invention

The present invention generally relates to a power-on reset circuit, and more specifically, to a technology of detecting levels of a plurality of internal power voltages including a boosting voltage and a core voltage as well as external power voltages to generate a power-on reset signal when all of the external power voltage and the plurality of internal power voltage are over a predetermined level.

2. Description of the Related Art

Generally, a device or a micro controller unit (MCU) floats registers in a chip before a power source is supplied. If the power source is supplied at this floating state, the register in the chip is set at an undesired state, so that the chip may be mis-operated. In addition, a macro block in the chip becomes instable when the power source is dropped below a predetermined voltage, so that the chip may be also mis-operated. In order to solve this problem, a power-on reset circuit is comprised in the chip.

In other words, the power-on reset circuit which does not comprise an additional reset circuit outside of the device self-generates a power-on reset signal, so that if the power source is ramped up at the initial stage and becomes down, initialize the chip to prevent the chip from being instable. As a result, the power-on reset circuit generates the power-on reset signal when a power voltage supplied in an internal circuit is lowered below a predetermined level.

FIG. 1 is a diagram illustrating a conventional power-on reset circuit.

The conventional power-on reset circuit comprises a power voltage dividing unit 10 and a sink unit 20.

The power voltage dividing unit 10 comprises resistors R1 and R2 connected serially between a power voltage VDD terminal and a ground voltage terminal. The power voltage dividing unit 10 divides a power voltage VDD depending on a resistance ratio and outputs the divided voltage to a node N1.

The sink unit 20 comprises a PMOS transistor PM1, a NMOS transistor NM1 and an inverter IV1. Here, the PMOS transistor PM1 and the NMOS transistor NM1 are connected serially between the power voltage VDD terminal and the ground voltage terminal.

The PMOS transistor PM1 which has a gate to receive a ground voltage is constantly turned on to apply a power voltage VDD level signal to a node N2. The NMOS transistor NM1 is controlled by a potential of the node N1, and applies a ground voltage level signal to the node N2. The inverter IV1 inverts a signal of the node N2.

The above-described conventional power-on reset circuit senses change of the power voltage VDD supplied to an internal circuit, and outputs a power-on reset signal PWRUP having a high level when the power voltage is over a predetermined level or the power-on reset signal PWRUP having a low level when the power voltage is below a predetermined level.

However, in the conventional power-on reset circuit, the external power voltage VDD increases ideally as shown in line A of FIG. 2, but a voltage drop phenomenon occurs actually below a predetermined level as shown in line B of FIG. 2 when the external power voltage VDD is supplied to the internal circuit.

In other words, although the power-on reset signal PWRUP is applied ideally as shown in line A when the external power voltage is over 1.2V, the voltage drop phenomenon occurs in the internal circuit actually as shown in line B, so that the power-on reset signal PWRUP is applied over 1.0V.

In this way, the conventional power-on reset circuit generates the power-on reset signal based on the level of the external power voltage ideally regardless of the change of the external power voltage, which results in mis-operations of the chip during a period C of FIG. 2.

### SUMMARY OF THE INVENTION

Accordingly, it is an object of the present invention to provide a power-on reset circuit for detecting levels of an external power voltage and internal power voltages such as a boosting voltage and a core voltage which are generated in response to the external power voltage.

In an embodiment, a power-on reset circuit comprises an external power voltage detecting unit, a plurality of internal power voltage detecting units and a selective output unit. The external power voltage detecting unit senses a level of an external power voltage. The plurality of internal power voltage detecting units sense levels of a plurality of internal power voltages, respectively. The output unit combines output signals from the external power voltage detecting unit and the internal power voltage detecting unit to output a power-on reset signal. Here, the output unit outputs a power-on reset signal when all of the external power voltage and the plurality of internal power voltage are over a predetermined level.

### BRIEF DESCRIPTION OF THE DRAWINGS

Other aspects and advantages of the present invention will become apparent upon reading the following detailed description and upon reference to the drawings in which:

FIG. 1 is a diagram illustrating a conventional power-on reset circuit;

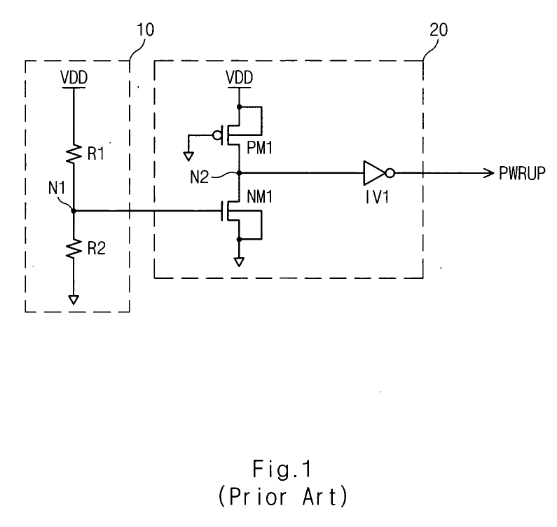

FIG. 2 is a graph illustrating the operation of the power-on reset circuit of FIG. 1;

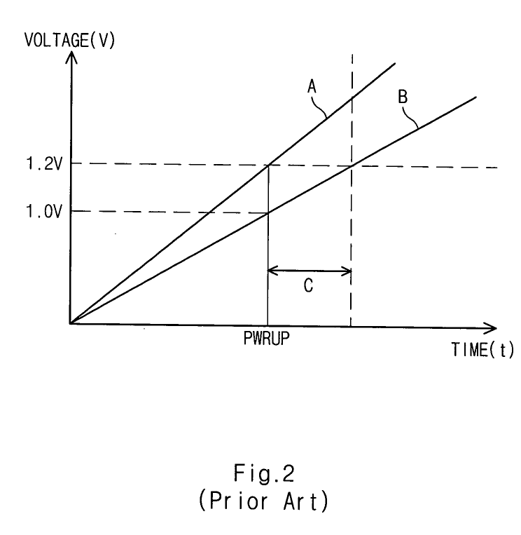

FIG. 3 is a diagram illustrating a power-on reset circuit according to an embodiment of the present invention; and

FIG. 4 is a graph illustrating the operation of the power-on reset circuit of FIG. 3.

### DETAILED DESCRIPTION OF THE PREFERRED EMBODIMENTS

The present invention will be described in detail with reference to the accompanying drawings.

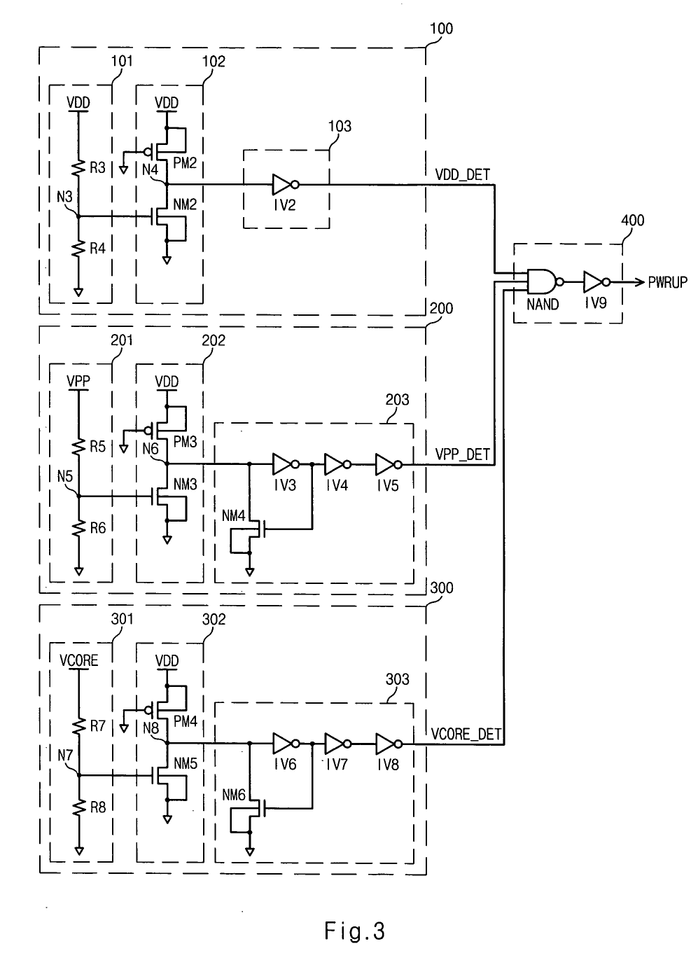

FIG. 3 is a diagram illustrating a power-on reset circuit according to an embodiment of the present invention.

In an embodiment, the power-on reset circuit comprises an external power voltage detecting unit 100, a boosting voltage detecting unit 200, a core voltage detecting unit 300 and a output unit 400.

The external power voltage detecting unit 100 comprises an external power voltage dividing unit 101 for dividing an external power voltage VDD, an external power voltage sink unit 102 for sinking an output signal from the external power voltage dividing unit 101, and a driving unit 103 for driving an output signal from the external power voltage sink unit 102 to output an external power voltage detecting signals VDD_DET.

The external power voltage dividing unit 101, which comprises resistors R3 and R4 connected serially between an external power voltage VDD terminal and a ground voltage terminal, divides the external power voltage VDD depending on a resistance ratio.

The external power voltage sink unit 102 comprises a PMOS transistor PM2 and a NMOS transistor NM2 which are connected serially between the external power voltage VDD terminal and the ground voltage terminal. The PMOS transistor PM2 which has a gate connected to the ground voltage terminal is constantly turned on to apply a level of the external power voltage. The NMOS transistor NM2 applies a ground voltage level to a node N4 in response to an output signal from a common node N3 of the resistors R3 and R4.

The driving unit 103 which comprises an inverter IV2 inverts an output signal from the node N4 and outputs the power voltage detecting signal VDD_DET.

The boosting power voltage detecting unit 200 comprises a boosting voltage dividing unit 201 for dividing a boosting voltage VDD, a boosting voltage sink unit 202 for sinking an output signal from the boosting voltage dividing unit 201, and a driving unit 203 for driving an output signal from the boosting voltage sink unit 202 to output a boosting voltage detecting signal VPP_DET.

The boosting voltage dividing unit 201, which comprises resistors R5 and R6 connected serially between a boosting voltage VPP terminal and the ground voltage terminal, divides the boosting voltage VPP depending on a resistance ratio.

The boosting voltage sink unit 202 comprises a PMOS transistor PM3 and a NMOS transistor NM3 which are connected serially between the boosting voltage VPP terminal and the ground voltage terminal. The PMOS transistor PM3 which has a gate connected to the ground voltage terminal is constantly turned on to apply a level of the boosting voltage level to a node N6. The NMOS transistor NM3 applies a ground voltage level to the node N6 in response to an output signal from a common node N5 of the resistors R5 and R6.

The driving unit 203 comprises a latch unit 204 and a buffer unit 205.

The latch unit 204 which comprises an inverter IV3 and a NMOS transistor NM4 maintains an output terminal of the boosting voltage sink unit 202 at a predetermined level. The inverter IV3 inverts an output signal from the boosting voltage sink unit 202, and the NMOS transistor NM4 applies the ground voltage level to the node N6 in response to an output signal from the inverter IV3.

The buffer unit 205, which comprises inverters IV4 and IV5 connected serially, buffers an output signal from the latch unit 204 and outputs the boosting voltage detecting signal VPP_DET.

The core voltage detecting unit 300 has the same configuration and function as those of the boosting voltage detecting unit 200. However, the core voltage detecting unit 300 divides a core voltage VCORE instead of the boosting voltage VPP, and sinks the core voltage VCORE to output a core voltage detecting signal VCORE_DET for detecting a level of the core voltage VCORE. Preferably, the NMOS transistors of each sink unit 102, 202 and 302 are configured to have the same width and length so as to have the same a threshold voltage vt.

The output unit 400 which comprises a NAND gate NAND and an inverter IV9 outputs a power-on reset signal PWRUP when the external power voltage VDD, the boosting voltage VPP and the core voltage VCORE are all over a predetermined level.

The NAND gate NAND performs a NAND operation on the external power voltage detecting signal VDD_DET, the boosting voltage detecting signal VPP_DET and the core voltage detecting signal VCORE_DET. The inverter IV9 inverts an output signal from the NAND gate NAND.

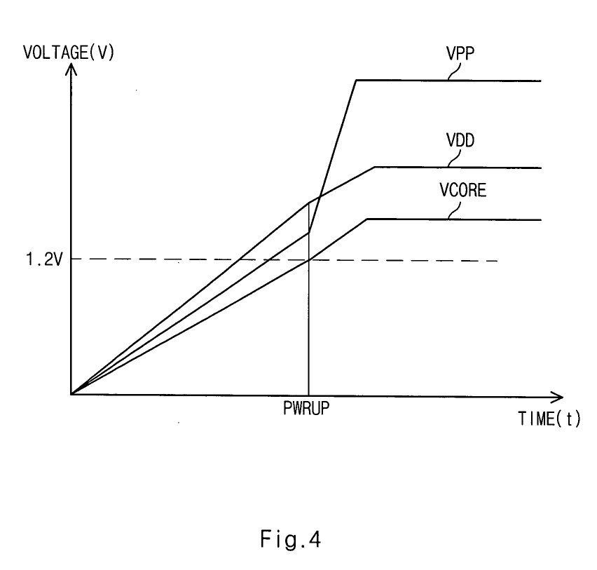

FIG. 4 is a graph illustrating the operation of the power-on reset circuit of FIG. 3.

First, the external power voltage dividing unit 101 divides the power voltage VDD and outputs the divided voltage to the node N3. Then, when the external power voltage VDD starts to rise, a potential of the node N3 also rises. When the potential of the node N3 is higher than a threshold voltage of the NMOS transistor NM2, the NMOS transistor NM2 is turned on to apply the ground voltage level to the node N4. As a result, the inverter IV2 outputs the external power voltage detecting signal VDD_DET having a high level.

Meanwhile, the boosting voltage dividing unit 201 divides the boosting voltage VPP and outputs the divided voltage to the node N5. Then, when the boosting voltage VPP rises to be higher than a threshold voltage of the NMOS transistor NM3, the NMOS transistor NM3 is turned on to apply the ground voltage level signal to the node N6. As a result, the driving unit 203 outputs the boosting voltage detecting signal VPP_DET having a high level. Here, the latch unit 204 of the driving unit 203 is comprised so as to keep a potential of the node N6 at the ground voltage level.

The detailed explanation on the core voltage detecting unit 300 is omitted because the core voltage detecting unit 300 has the same configuration and operation as those of the boosting voltage detecting unit 200.

When the external power voltage VDD, the boosting voltage VPP and the core voltage VCORE are all over a predetermined level, the external power voltage detecting signal VDD_DET, the boosting voltage detecting signal VPP_DET and the core voltage detecting signal VCORE_DET become all at the high level, so that the output unit 400 outputs the power-up signal PWRUP having a high level.

As shown in FIG. 4, in the power-on reset circuit according to the embodiment of the present invention, the power-up signal PWRUP is outputted when the external power voltage VDD, the core voltage VCORE and the boosting voltage VPP are all over a predetermined level.

As described above, a power-on reset circuit according to an embodiment of the present invention senses levels of internal power voltage including a boosting voltage and a core voltage as well as an external power voltage, and outputs a power-on reset signal when the voltages are all over a predetermined level, thereby preventing mis-operations of the chip.

While the invention is susceptible to various modifications and alternative forms, specific embodiments have been shown by way of example in the drawings and described in detail herein. However, it should be understood that the invention is not limited to the particular forms disclosed. Rather, the invention covers all modifications, equivalents, and alternatives falling within the spirit and scope of the invention as defined in the appended claims.

What is claimed is:

1. A power-on reset circuit comprising:
an external power voltage detecting unit for detecting a level of an external power voltage;
a plurality of internal power voltage detecting units for detecting levels of a plurality of internal power voltages, respectively; and
a output unit for combining output signals from the external power voltage detecting unit and the internal power voltage detecting unit to output a power-on reset signal,
wherein the output unit outputs the power-on reset signal when all of the external power voltage and the plurality of internal power voltage are over a predetermined level.

2. The power-on reset circuit according to claim 1, wherein the external power voltage detecting unit comprises:
an external power voltage dividing unit for dividing the external power voltage;
an external power voltage sink unit for sinking an output signal from the external power voltage dividing unit; and
a driving unit for driving an output signal from the external power voltage sink unit to output a detecting signal.

3. The power-on reset circuit according to claim 2, wherein the external power voltage dividing unit comprises a plurality of resistors.

4. The power-on reset circuit according to claim 2, wherein the external power voltage sink unit comprises:
a PMOS transistor, which is constantly turned on, having a drain to receive the level of the external power voltage; and
a NMOS transistor having a drain to receive a ground voltage level in response to an output signal from the internal power voltage dividing unit.

5. The power-on reset circuit according to claim 2, wherein the driving unit comprises an inverter.

6. The power-on reset circuit according to claim 1, wherein each of the plurality of internal power voltage detecting units comprises:
an internal power voltage dividing unit for dividing one of the plurality of internal power voltages;
the internal power voltage sink unit for sinking an output signal from the internal power voltage dividing unit; and
a driving unit for driving an output signal from the internal power voltage sink unit to output the detecting signal.

7. The power-on reset circuit according to claim 6, wherein the internal power voltage dividing unit comprises a plurality of resistors.

8. The power-on reset circuit according to claim 6, wherein the internal power voltage sink unit comprises:
a PMOS transistor, which is constantly turned on, having a drain to receive the level of the external power voltage; and
a NMOS transistor having a drain to receive a ground voltage level in response to an output signal from the internal power voltage dividing unit.

9. The power-on reset circuit according to claim 6, wherein the driving unit comprises:
a latch unit for maintaining an output signal from the internal power voltage sink unit at a predetermined level; and
a buffer unit for buffering an output signal from the latch unit to output the detecting signal.

10. The power-on reset circuit according to claim 9, wherein the latch unit comprises:
an inverter for inverting an output signal from the internal power voltage sink unit; and
a NMOS transistor for applying a ground voltage level to an input terminal of the inverter in response to an output signal from the inverter.

11. The power-on reset circuit according to claim 1, wherein each of the plurality of internal power voltage detecting units senses levels of a boosting voltage and a core voltage.

12. The power-on reset circuit according to claim 1, wherein the output unit comprises:
a logic operation unit for performing a logic operation on output signals from the external power voltage detecting unit and the plurality of internal power voltage detecting units; and
an inverting unit for inverting an output signal from the logic operation unit.

13. The power-on reset circuit according to claim 12, wherein the logic operation unit comprises a NAND gate.

14. The power-on reset circuit according to claim 1, wherein the plurality of internal power voltages are a core voltage and a boosting voltage.
